(19) United States
(12) Patent Application Publication
(10) Pub. No.: US 2026/0075901 A1
(43) Pub. Date: Mar. 12, 2026

(54) SEMICONDUCTOR DEVICES WITH DRAIN-SOURCE CONNECTION FOR AVALANCHE BREAKDOWN

(71) Applicant: Wolfspeed, Inc., Durham, NC (US)

(72) Inventors: Rahul R. Potera, Apex, NC (US); Sei-Hyung Ryu, Cary, NC (US)

(21) Appl. No.: 18/826,969

(22) Filed: Sep. 6, 2024

(51) Int. Cl. H01L 29/08; H01L 29/10; H01L 29/417; H01L 29/808

(52) U.S. Cl. CPC H10D 62/149; H10D 30/831; H10D 62/343; H10D 64/252

(57) ABSTRACT

A vertical junction field effect (JFET) semiconductor device according to some embodiments includes a drift layer, a channel layer on the drift layer, and a plurality of alternating trenches and mesas in the channel layer, wherein a first plurality of the trenches includes gate contact regions. A source metallization is on the mesas. The device includes a second different than the first plurality of trenches, wherein the source metallization is electrically connected to the drift layer at a bottom of the second trench.

### TECHNICAL FIELD

The present disclosure relates to semiconductor devices and, more particularly, to vertical power semiconductor devices.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate metal layers, and one or more gate buses and/or gate metal layers that electrically connect the gate pad to the gate metal layers. The gate metal layers are disposed adjacent the respective channel regions. Power JFETs are typically normally-on devices, meaning that a JFET conducts current when a voltage of 0 volts is applied to the gate. When a sufficiently negative voltage (referred to as the threshold voltage, VT) is applied to the gate structure, the channel is pinched off and the JFET ceases to conduct current.

### SUMMARY

A vertical junction field effect (JFET) semiconductor device according to some embodiments includes a drift layer, a channel layer on the drift layer, and a plurality of alternating trenches and mesas in the channel layer, wherein a first plurality of the trenches includes gate contact regions. A source metallization is on the mesas. The device includes a second different than the first plurality of trenches, wherein the source metallization is electrically connected to the drift layer at a bottom of the second trench.

In some embodiments, the source metallization may extend into the second trench.

The vertical JFET semiconductor device may further include an electrical contact in the second trench, wherein the electrical contact is electrically connected to the source metallization outside the second trench.

The second trench may extend deeper into the drift layer than the first plurality of trenches. In particular, the second trench may extend about two to three times deeper into the drift layer than the first plurality of trenches.

The corners of a pair of mesas of the plurality of mesas adjacent the second trench may be rounded, angled or chamfered.

A first one of the first plurality of trenches may be directly adjacent a second one of the first plurality of trenches, and a distance between the first and second ones of the first plurality of trenches may be greater than a distance between the second trench and a third one of the first plurality of trenches that is directly adjacent to the second trench.

The vertical JFET semiconductor device may further include a doped region beneath the second trench. The doped region may have a conductivity type that is the same as a conductivity type of a drift region of the vertical JFET semiconductor device.

The second trench may be deeper than the first plurality of trenches.

The doped region may have a greater doping concentration than the drift region. In particular, the doped region may have a doping concentration greater than about 1.25 times a doping concentration of the drift region.

The at least one trench may be enclosed by a single mesa.

The vertical JFET semiconductor device may further include a plurality of second trenches, wherein the source metallization is electrically connected to the drift layer at bottoms of the plurality of second trenches.

The bottoms of the second plurality of the trenches may be conductively connected to the source metallization.

The number of the first plurality of trenches may be about equal to a number of the plurality of second trenches.

Each of the plurality of second trenches may be adjacent at least one of the first plurality of trenches.

A vertical JFET semiconductor device according to some embodiments includes a drift layer, a channel layer on the drift layer, and a plurality of alternating trenches and mesas in the channel layer, wherein a first plurality of the trenches include gate contact regions. The vertical JFET semiconductor device includes a source metallization on the plurality of alternating trenches and mesas. The source metallization is electrically connected to the drift layer at a bottom of a second trench that is different from the first plurality of trenches.

The vertical JFET semiconductor device may further include a plurality of second trenches, wherein the source metallization is electrically connected to the drift layer at bottoms of the plurality of second trenches.

A vertical JFET semiconductor device according to some embodiments includes a drift layer, a channel layer on the drift layer, and a plurality of alternating trenches and mesas in the channel layer within an active region of the device. The plurality of trenches include a first plurality of the trenches having a first depth and a second plurality of trenches in having a second depth that is greater than the first depth.

The vertical JFET semiconductor device may further include gate contact regions within the first plurality of trenches, and a source metallization. The source metallization is electrically connected to the drift layer at bottoms of the second plurality of trenches.

A method of forming vertical JFET semiconductor device includes providing a drift layer, forming a channel layer on the drift layer, and forming a plurality of alternating trenches and mesas in the channel layer within an active region of the device. The plurality of trenches include a first plurality of the trenches having a first depth and a second plurality of trenches having a second depth that is greater than the first depth. The method may further include forming gate contacts within the first plurality of trenches, and forming a source metallization on the device, wherein the source metallization is electrically connected to the drift layer at bottoms of the second plurality of trenches.

### BRIEF DESCRIPTION OF DRAWINGS

FIG. 1 illustrates a cell of a vertical JFET semiconductor device.

FIG. 2 illustrates, in plan view, a conventional layouts of a vertical JFET semiconductor device.

FIG. 3 is a cross-sectional view of a conventional JFET structure.

FIGS. 4A, 4B, 5A, 5B, 6A and 6B are cross-sectional views of JFET structures according to some embodiments.

FIG. 7 is a plan view that illustrates a layout of a JFET structure according to some embodiments.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected”or “directly coupled”to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art. Like reference numbers refer to like elements throughout the description.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices, such as MOSFETs, insulated gate bipolar transistors (IGBTs) and other types of devices.

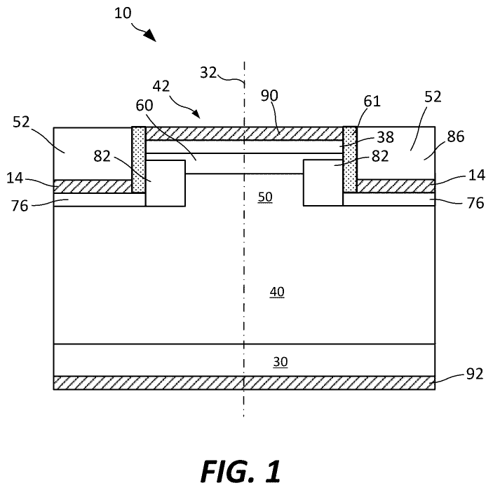

An n-channel vertical JFET structure 10 is shown in FIG. 1. The vertical JFET structure 1 includes an n+ substrate 30 on which an n-drift layer 40 is formed. An n-type channel region 50 is on the drift layer 40, and an n+ source layer 60 is on the channel region 50. An n++ source contact layer 38 is on the n+ source layer 60. A drain ohmic contact 92 is on the substrate 30, and a source metal silicide layer 90 is on the source contact layer 38. The channel region 50, source layer 60 and source contact layer 38 are provided as part of a mesa stripe 42 above the drift layer 40. Trenches 52 are formed in the structure 10 adjacent the mesa stripe 42.

A p+ gate region 82 is provided as part of the mesa stripe 42 adjacent the channel region 50. A p++ gate contact region 76 is provided adjacent the gate region 82, and a gate ohmic contact, or gate finger, 14 is formed on the gate contact region 76 in the trenches 52 on opposite sides of the mesa stripe 42. To form the gate finger 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An insulation layer 86 is formed in the trenches 52 on the gate finger 14 and the gate contact region 76. The insulation layer 86 may be formed from silicon oxide. Oxide/nitride spacer layers 61 are provided on sidewalls of the mesa stripe 42.

The vertical JFET unit cell structure 10 is symmetrical about the axis 32 and includes two gate regions 82 as part of the mesa stripe 42 on opposite sides of the channel region 50.

The channel of the vertical JFET structure 10 is formed within the mesa stripe 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length (i.e., the distance carriers travel through the channel from the source to the drain) is chosen based on a trade-off between low on-resistance in the on-state and resistance to drain-induced barrier lowering (DIBL) in the off-state. A p-channel JFET may have a similar structure, but the conductivity types are reversed from those shown in FIG. 1.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) V_{GS} is applied to the gate regions 82. When no voltage is applied to the gate region 82, charge carriers can flow freely from the source layer 60 through the channel region 50 and the drift layer 40 to the substrate 30.

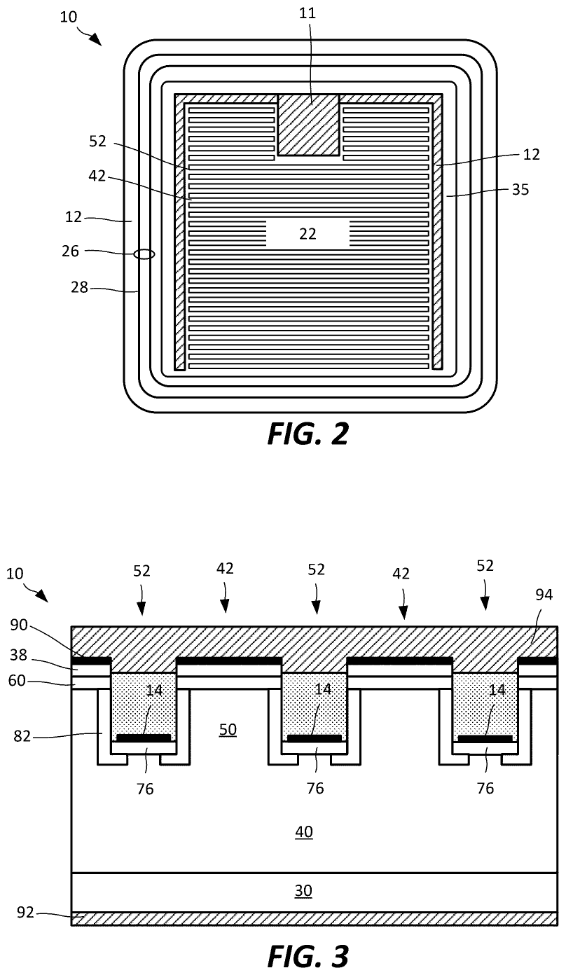

FIG. 2 illustrates, in plan view, a conventional layout of a vertical JFET semiconductor device 10. Referring to FIGS. 1 and 2, a JFET device 10 is formed on a substrate 30. The device 10 includes an active region 22 in which a plurality of alternating mesa stripes 42 and trenches 52 are formed. The active region 22 is surrounded by an edge termination region 26 in which a plurality of guard rings 28 are formed. Guard rings 28 are shown as an example of an edge termination for a power semiconductor device. However, other termination structures, such as field rings, junction termination extension (JTE) regions, etc., can be provided in the edge termination region 26.

A metal silicide region 35 is formed on an upper surface of the device within the active region 22 in areas other than on the mesa stripes 42. The metal silicide region 35, which may for example be nickel silicide, forms the gate fingers 14 within the trenches 52. A gate contact pad 11 is formed on the upper surface of the device 10 within the metal silicide region 35, and a pair of gate buses 12 (also referred to as gate runners 12) extend from the gate contact pad 11 around the outer periphery of the active region 22 adjacent the ends of the mesa stripes 42 and trenches 52 of the device 10A. The gate contact pad 11 and the gate buses 12 may include a conductive material such as a metal silicide and/or a metal layer.

The metal silicide region 35 provides a low resistance current path between the gate buses 12/gate contact pad 11 and the gate fingers 14 (FIG. 1) that are formed within the trenches 52.

In the JFET device 10 a gate voltage applied to the gate contact pad 11 is conducted through the gate bus 12 and metal silicide region 35 to the gate ohmic contacts 14 within the trenches 52.

FIG. 3 illustrates a portion of the device 10 in cross-section. In particular, FIG. 3 illustrates a plurality of alternating trenches 52 and mesa stripes 42, with a gate finger 14 within each trench 52. FIG. 3 also shows a source metallization 94 that contacts the source metal contacts 90 on each mesa 42.

In a switching power device such as a JFET device, a phenomenon referred to as unclamped inductive switching (UIS) may occur when the device is placed under high reverse bias. UIS occurs when current undesirably flows from the drain of the device back through the gate of the device. This subjects the device simultaneously to high current and high voltage, which dissipates a high amount of power in the device and may cause the device to fail when the UIS current exceeds a threshold limit. The ability to handle UIS current is an important quality of a switching power device.

If UIS current is limited by current crowding and filamentation in a part of the semiconductor structure, UIS weakness can be addressed by making the junction breakdown more uniform so that heat is dissipated more uniformly across the device. If UIS current is limited by the current carrying regions outside the semiconductor device, UIS weakness can be addressed by increasing ampacity at those choke points.

When UIS current is not limited in those ways, then gate-drain UIS current causes a voltage drop across the gate resistance, which biases the gate of the device. At sufficient UIS current, this UIS-induced gate bias can exceed the local threshold voltage (VT) of the device and turn on the channel locally (i.e., in the vicinity of the induced gate bias). The channel current induced by UIS biasing will heat up the device locally creating a hotspot in the device. This further reduces VT and increases leakage near the hotspot. This condition creates a positive feedback loop, referred to as a thermal runaway condition, that can cause the device to fail catastrophically at the hotspot.

The main blocking junction of a JFET device at which drain breakdown happens is the gate-drain PN junction. Most JFETs are normally-on devices that block drain voltage with negative gate bias. In such devices, the gate to drain PN junction is biased at a higher voltage than the source to drain junction, which causes UIS breakdown to be more likely to occur at the gate to drain PN junction.

The gate to drain capacitance (C_{GD}) may be high in the JFET design shown in FIGS. 1 to 3 because of gate-drain junction being the main blocking junction under reverse bias conditions. In a direct drive application, high C_{GD} results in high Miller capacitance, which requires a high gate charge and high switching loss to drive the JFET.

Some embodiments described herein connect some of the trench regions of a JFET to the source potential rather than to the gate potential in order to divert some of the C_{GD} to drain-source capacitance (C_{DS}). This may additionally improve the avalanche capability of the JFET by adding drain-source avalanche junctions.

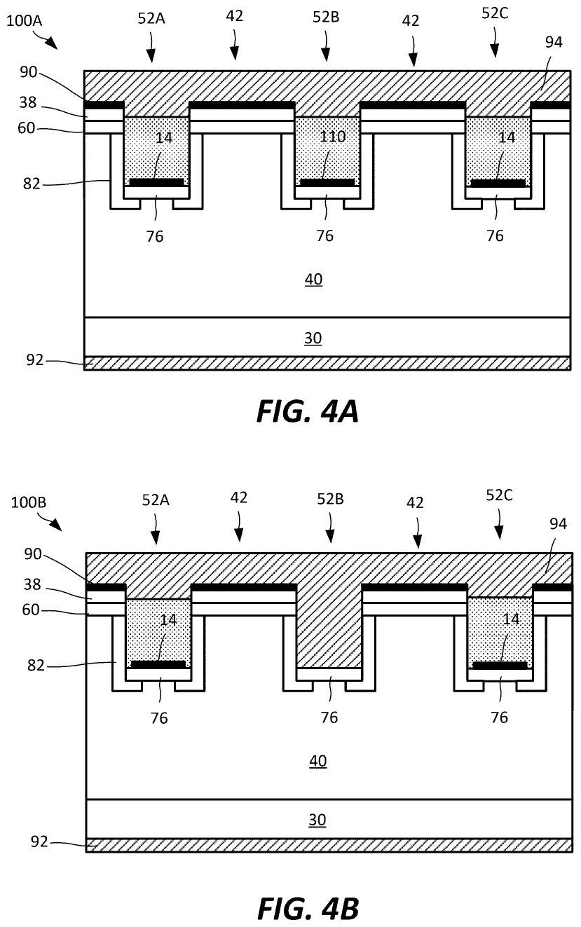

For example, FIG. 4A is a cross-sectional view of a portion of a JFET device 100A according to some embodiments. In particular, FIG. 4A illustrates a plurality of alternating trenches 52A, 52B, 52C and mesa stripes 42. A gate finger 14, which may, for example, be a metal silicide layer, is provided within the trenches 52A and 52C. Within the trenches 52A, 52C, the gate finger 14 is formed on the gate contact layer 76 and is electrically connected to the gate contact pad 11 via the metal silicide region 35 and the gate buses 12 as in the conventional structure shown in FIGS. 1 to 3. A metal silicide layer 110 is also provided in the trench 52B. However, in the device 100A, the metal silicide layer 110 is not electrically connected to the gate contact pad 11, but rather is electrically connected to the source metallization 94 at a location outside of the plane of FIG. 4A. Thus, according to some embodiments the source metallization 94 is electrically connected to the drift layer 40 through a P-N junction between the gate contact layer 76 and the gate regions 82 on one hand and the drift layer 40 on the other hand.

FIG. 4B is a cross-sectional view of a portion of a JFET device structure 100B according to some further embodiments. The JFET structure 100B also includes a plurality of alternating trenches 52A, 52B, 52C and mesa stripes 42. Within the trenches 52A, 52C, the gate finger 14 is formed on the gate contact layer 76 and is electrically connected to the gate contact pad 11 via the metal silicide region 35 and the gate buses 12 as in the conventional structure shown in FIGS. 1 to 3. However, within the trench 52B, the source metallization 94 extends into the trench and contacts the gate contact layer 76. Optionally, a metal silicide layer, such as the metal silicide layer 110 shown in FIG. 4A, may be formed on the gate contact layer 76, and the source metallization 94 may contact the metal silicide layer 110. Thus, according to some embodiments the source metallization 94 is electrically connected to the drift layer 40 through a P-N junction between the gate contact layer 76 and the gate regions 82 on one hand and the drift layer 40 on the other hand.

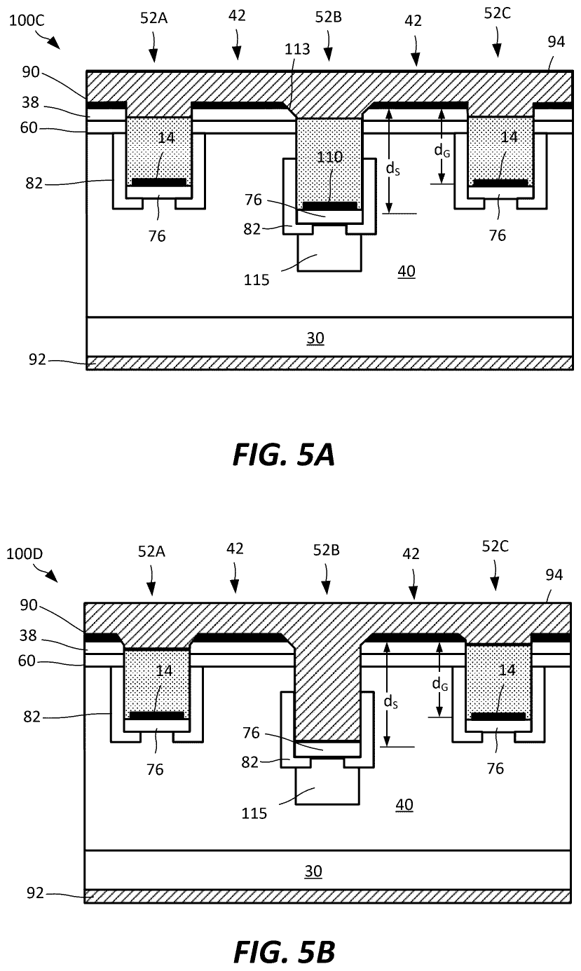

FIGS. 5A and 5B illustrate JFET structures according to further embodiments. In particular, FIGS. 5A and 5B illustrate a JFET structures 100C, 100D in which the trenches 52B through which source contact is made to the drift layer 40 extends deeper into the drift layer 40 than the trenches 52A and 52C. For example, the trenches 52B in which source contact is made to the gate contact layer 76 (referred to herein as a “source trenches”) may have a depth d_{S}, while the trenches 52A and 52C in which the gate fingers 14 are formed (referred to herein as “gate trenches”) may have a depth d_{G} which is less than d_{S}. In particular embodiments, the gate trenches 52A, 52C may have a depth of about 2 microns to 3 microns, and the source trenches 52B may be about 1.25 to 3 times deeper than the gate trenches 52A, 52C, e.g., about 2.5 microns to 6 microns deep. This may enhance the avalanche current carrying capability and/or gate-drain capacitance of the structure.

FIGS. 5A and 5B also illustrate an optional doped region 115 beneath the source trenches 52B. The doped region 115 may have the same conductivity type as the drift layer 40 (e.g., n-type) and may be doped with a doping concentration that is at least about 1.25 times the doping concentration of the drift layer 40, up to a maximum doping concentration of about 1E19 cm-3. It will be appreciated that the doped region 115 may also be provided in the structures 100A, 100B shown in FIGS. 4A and 4B. The doped regions 115 may extend to a depth that is up to about 1.25 to 3 times a depth of the gate trenches 52A, 52B. The depth of the doped regions may be selected for the drift layer 40 to have a minimum thickness that is large enough to sustain a desired reverse blocking voltage. The optional doped regions 115 may also enhance the avalanche current carrying capability and/or gate-drain capacitance of the structure.

FIGS. 5A and 5B also illustrate that corners 113 of the mesas adjacent to the source trench 52B may be slightly rounded, chamfered or angled relative to the mesa corners adjacent the gate trenches 52A, 52C due to the increased depth of the source trench 52B.

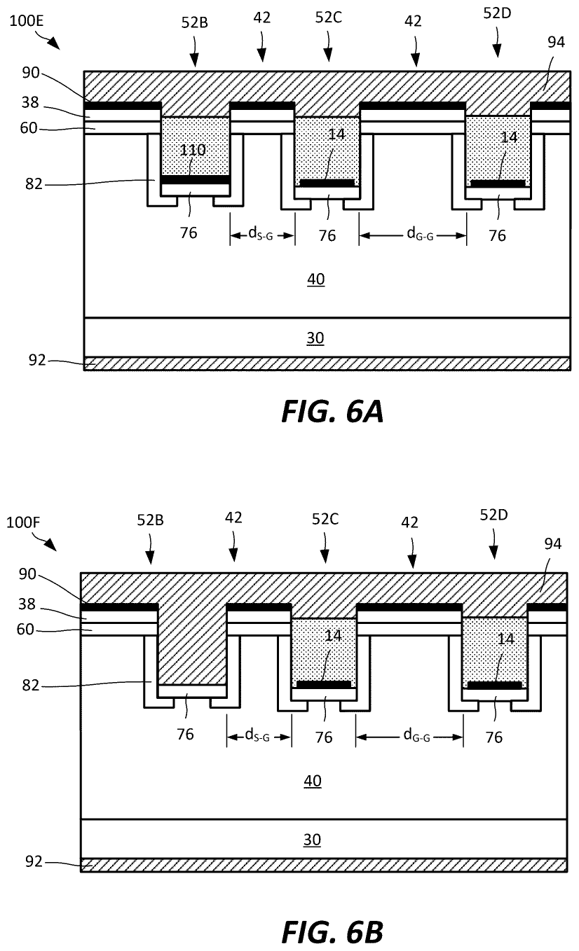

FIGS. 6A and 6B illustrate JFET structures according to further embodiments. In particular, FIGS. 6A and 6B illustrate a JFET structures 100E, 100F having a source trench 52B adjacent to a first gate trench 52C. A second gate trench 52D is on the opposite side of the first gate trench 52C from the source trench 52B. As shown in FIGS. 6A and 6B, in some embodiments, a lateral spacing d_{S-G} between the source trench 52B and the adjacent first gate trench 52C is less than a lateral spacing d_{G-G} between the first gate trench 52C and the second gate trench 52D. For example, in some embodiments, the lateral spacing d_{G-G} between gate trenches may be about 1.2 microns, and the lateral spacing d_{S-G} between the source trench 52B and the adjacent first gate trench 52C may be less than about 1.2 microns. Making the lateral spacing d_{S-G} between the source trench 52B and the adjacent first gate trench 52C smaller than the lateral spacing d_{G-G} between gate trenches may enhance the reverse voltage blocking capability of the structure.

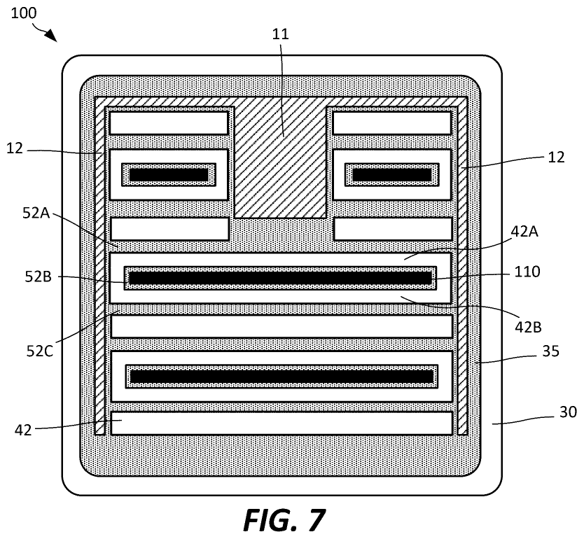

FIG. 7 illustrates a device layout of a JFET device structure 100 according to some embodiments. The device layout of the JFET device structure 100 comprises a substrate 30 on which a plurality of alternating trench/mesa structures are formed, including a source trench 52B between first and second gate trenches 52A, 52C. The trenches are separated by mesa stripes 42, including a first mesa stripe 42A between the source trench 52B and the first gate trench 52A and a second mesa stripe 42B between the source trench 52B and the second gate trench 52B. Metal silicide layers 110 are formed within the source trenches and are connected to a source metallization 94 (as shown, for example, in FIGS. 4A and 4B) by means of interlayer metallizations (not shown).

As shown in FIG. 7, the first mesa stripe 42A and the second mesa stripe 42B on opposite sides of the source trench 52B may be connected together at opposite ends thereof to form a continuous mesa around the source trench 52B, to thereby isolate the source trench 52B and the metal silicide layer 110 therein from the metal silicide region 35, the gate buses 12, the gate fingers 14 (e.g., as shown in FIGS. 4A and 4B) and the gate pad 11.

In some embodiments, the mesa stripes may not be connected together to isolate the source trench 52B, and the metal silicide region 35 may be omitted from the ends of the source trenches to isolate the source trenches from the remainder of the structure.

In some embodiments, a JFET device structure 100 may have equal numbers of gate trenches 52A, 52C and source trenches 52B. However, in some embodiments, there may be more gate trenches 52A, 52C than source trenches 52B, and in other embodiments, the structure 100 may have more source trenches 52B than gate trenches 52A, 52C depending on the design objectives of the device. In some embodiments, each of the source trenches 52B is adjacent to at least one gate trench 52A, 52C.

Providing more source trenches than gate trenches may improve the avalanche current handling capability and/or gate-drain capacitance of the device at the expense of increasing the drain-source on-resistance (Rdson) of the device. On the other hand, providing more gate trenches than source trenches may reduce the avalanche current handling capability and/or gate-drain capacitance of the device while lowering Rdson.

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The term “in electrically conductive contact” means that two elements are in direct or indirect contact in such a way that electrical current can flow from one element to another. At least part of the connection between the two elements may be electrically resistive.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A vertical junction field effect (JFET) semiconductor device, comprising:
a drift layer;
a channel layer on the drift layer;
a plurality of alternating trenches and mesas in the channel layer, wherein a first plurality of the trenches comprises gate contact regions;
a source metallization on the mesas; and
a second trench different than the first plurality of trenches, wherein the source metallization is electrically connected to the drift layer at a bottom of the second trench.

2. The vertical JFET semiconductor device of claim 1, wherein the source metallization extends into the second trench.

3. The vertical JFET semiconductor device of claim 1, further comprising:
an electrical contact in the second trench, wherein the electrical contact is electrically connected to the source metallization outside the second trench.

4. The vertical JFET semiconductor device of claim 1, wherein the second trench extends deeper into the drift layer than the first plurality of trenches.

5. The vertical JFET semiconductor device of claim 1, wherein the second trench extends about two to three times deeper into the drift layer than the first plurality of trenches.

6. The vertical JFET semiconductor device of claim 1, wherein corners of a pair of mesas of the plurality of mesas adjacent the second trench are rounded, angled or chamfered.

7. The vertical JFET semiconductor device of claim 1, wherein a first one of the first plurality of trenches is directly adjacent a second one of the first plurality of trenches, wherein a distance between the first and second ones of the first plurality of trenches is greater than a distance between the second trench and a third one of the first plurality of trenches that is directly adjacent to the second trench.

8. The vertical JFET semiconductor device of claim 1, further comprising a doped region beneath the second trench, wherein the doped region has a conductivity type that is the same as a conductivity type of a drift region of the vertical JFET semiconductor device.

9. The vertical JFET semiconductor device of claim 8, wherein the second trench is deeper than the first plurality of trenches.

10. The vertical JFET semiconductor device of claim 8, wherein the doped region has a greater doping concentration than the drift region.

11. The vertical JFET semiconductor device of claim 8, wherein the doped region has a doping concentration greater than about 1.25 times a doping concentration of the drift region.

12. The vertical JFET semiconductor device of claim 1, wherein the second trench is enclosed by a single mesa.

13. The vertical JFET semiconductor device of claim 1, further comprising a plurality of second trenches, wherein the source metallization is electrically connected to the drift layer at bottoms of the plurality of second trenches.

14. The vertical JFET semiconductor device of claim 13, wherein bottoms of the plurality of second trenches are conductively connected to the source metallization.

15. The vertical JFET semiconductor device of claim 14, wherein a number of the first plurality of trenches is about equal to a number of the plurality of second trenches.

16. The vertical JFET semiconductor device of claim 14, wherein each of the plurality of second trenches is adjacent one of the first plurality of trenches.

17. A vertical junction field effect (JFET) semiconductor device, comprising:
a drift layer;
a channel layer on the drift layer;
a plurality of alternating trenches and mesas in the channel layer, wherein a first plurality of the trenches comprise gate contact regions; and
a source metallization on the plurality of alternating trenches and mesas;
wherein the source metallization is electrically connected to the drift layer at a bottom of a second trench that is different from the first plurality of trenches.

18. The vertical JFET semiconductor device of claim 17, further comprising a plurality of second trenches, wherein the source metallization is electrically connected to the drift layer at bottoms of the plurality of second trenches.

19. A vertical junction field effect (JFET) semiconductor device, comprising:
a drift layer;
a channel layer on the drift layer; and
a plurality of alternating trenches and mesas in the channel layer within an active region of the device, wherein the plurality of trenches comprise a first plurality of the trenches having a first depth and a second plurality of trenches in having a second depth that is greater than the first depth.

20. The vertical JFET semiconductor device of claim 19, further comprising:
gate contact regions within the first plurality of trenches; and
a source metallization, wherein the source metallization is electrically connected to the drift layer at bottoms of the second plurality of trenches.

21. A method of forming vertical junction field effect (JFET) semiconductor device, comprising:
providing a drift layer;
forming a channel layer on the drift layer; and
forming a plurality of alternating trenches and mesas in the channel layer within an active region of the device, wherein the plurality of trenches comprise a first plurality of the trenches having a first depth and a second plurality of trenches having a second depth that is greater than the first depth.

22. The method of claim 21, further comprising:
forming gate contacts within the first plurality of trenches; and
forming a source metallization on the device, wherein the source metallization is electrically connected to the drift layer at bottoms of the second plurality of trenches.
